(19) United States
(12) Patent Application Publication
(10) Pub. No.: US 2026/0096295 A1
(43) Pub. Date: Apr. 2, 2026

(54) ORGANIC LIGHT-EMITTING ELEMENT AND METHOD FOR MANUFACTURING THE SAME

(71) Applicant: TAIZHOU GUANYU TECHNOLOGY CO., LTD., ZHEJIANG PROVINCE (CN)

(72) Inventors: RENHUI RUAN, ZHEJIANG PROVINCE (CN); HUEI-SIOU CHEN, TAIPEI CITY (TW)

(21) Appl. No.: 19/312,332

(22) Filed: Aug. 28, 2025

(30) Foreign Application Priority Data
Sep. 30, 2024 (CN) 202411383787.4

(51) Int. Cl. H10K 59/122; H10K 50/822; H10K 59/12

(52) U.S. Cl. CPC H10K 59/122; H10K 50/822; H10K 59/1201

(57) ABSTRACT

An organic light-emitting element includes a substrate, a first bottom electrode, an organic light-emitting layer structure, a first top electrode, and a second top electrode. The first bottom electrode is located on the substrate. The organic light-emitting layer structure is located on the first bottom electrode. The first top electrode and the second top electrode are located on the organic light-emitting layer structure. Extension directions of the first top electrode and the second top electrode are substantially perpendicular to an extension direction of the first bottom electrode, and the first top electrode and the second top electrode are separated from each other.

### TECHNICAL FIELD

The present disclosure relates to an organic light-emitting element and a method for manufacturing the same, and more particularly, to an organic light-emitting element including an organic light-emitting diode (OLED) structure and a method for manufacturing the same.

### BACKGROUND

Currently, a fine metal mask (FMM) is commonly used in a coating step for a light-emitting layer of an organic light-emitting element, or white light in combination with a color film is adopted for performing the process. Pixel fineness or resolution of pixels manufactured by the above process is not good.

### SUMMARY

In the present disclosure, an organic light-emitting element includes a substrate, a first bottom electrode, an organic light-emitting layer structure, a first top electrode, and a second top electrode. The first bottom electrode is located on the substrate. The organic light-emitting layer structure is located on the first bottom electrode. The first top electrode and the second top electrode are located on the organic light-emitting layer structure. Extension directions of the first top electrode and the second top electrode are substantially perpendicular to an extension direction of the first bottom electrode, and the first top electrode and the second top electrode are separated from each other.

In the present disclosure, a method for manufacturing an organic light-emitting element includes providing a substrate; disposing a first bottom electrode on the substrate; forming a blocking strip structure on the substrate, wherein the blocking strip structure includes a first blocking strip and a second blocking strip located on the first blocking strip; forming an organic light-emitting layer structure on the first bottom electrode and the blocking structure; and forming a top electrode material layer on the blocking structure and the substrate, such that the top electrode material layer is cut off by the second blocking strip to form a first top electrode and a second top electrode that are separated from each other.

In some embodiments, the organic light-emitting element further includes a pixel defining layer located on the substrate, the first top electrode, the second top electrode, and a local upper surface of the pixel defining layer define a groove, and the first top electrode and the second top electrode are separated by the groove.

In some embodiments, the first top electrode partially extends onto the pixel defining layer, and a thickness of the first top electrode tapers towards the second top electrode.

In some embodiments, an end portion of the first top electrode extends onto the pixel defining layer and includes an upwardly extending protrusion portion.

In some embodiments, the organic light-emitting element further includes a capping layer covering the first top electrode and the second top electrode and partially extending into the groove.

In some embodiments, the organic light-emitting element further includes a blocking strip structure located on the substrate, and the first top electrode and the second top electrode are separated by the blocking strip structure.

In some embodiments, the blocking strip structure further includes a first blocking strip and a second blocking strip. The first blocking strip is located between the first top electrode and the second top electrode, the second blocking strip is located on the first blocking strip, and a width of the second blocking strip is greater than a width of the first blocking strip.

In some embodiments, a sidewall of the first blocking strip is recessed relative to a sidewall of the second blocking strip.

In some embodiments, the sidewall of the first blocking strip comprise a concave curved surface.

In some embodiments, the organic light-emitting element further includes an electrode material layer located on an upper surface and sidewalls of the blocking strip structure, and separated from the first top electrode and the second top electrode.

In some embodiments, the electrode material layer comprises an extension portion located on the sidewalls of the blocking strip structure and tapering towards the substrate.

In some embodiments, the extension directions of the first top electrode and the second top electrode are substantially parallel to an extension direction of the blocking strip structure.

In some embodiments, the organic light-emitting structure includes a first organic light-emitting layer and a second organic light-emitting layer. The first organic light-emitting layer is located between the first bottom electrode and the first top electrode, and the second organic light-emitting layer is located between the first bottom electrode and the second top electrode, wherein the first organic light-emitting layer and the second organic light-emitting layer are separated by the blocking strip structure.

In some embodiments, the organic light-emitting structure includes a first organic light-emitting layer, a second organic light-emitting layer, and an organic material layer. The first top electrode and the second top electrode are respectively located on the first organic light-emitting layer and the second organic light-emitting layer, the organic material layer is located on the blocking strip structure and is separated from the first organic light-emitting layer and the second organic light-emitting layer.

In some embodiments, the organic light-emitting element further includes a pixel defining layer located on the substrate and located between the first top electrode and the second top electrode, wherein the blocking strip structure is located on the pixel defining layer.

In some embodiments, the method for manufacturing the organic light-emitting element further includes forming a pixel defining layer on the substrate and partially covering the first bottom electrode; and forming the blocking strip structure on the pixel defining layer, wherein the top electrode material layer is cut off by a height difference between the second blocking strip and the pixel defining layer.

In some embodiments, forming the blocking strip structure includes: forming a blocking material layer on the pixel defining layer; forming a second blocking strip on the blocking material layer; and etching the blocking material layer according to a pattern of the second blocking strip to form the first blocking strip, such that a sidewall of the first blocking strip is recessed relative to a sidewall of the second blocking strip.

In some embodiments, the method for manufacturing the organic light-emitting element further includes: removing the blocking strip structure to form a groove defined by the first top electrode, the second top electrode, and a local upper surface of the pixel defining layer.

In some embodiments, the method for manufacturing the organic light-emitting element further includes: forming a capping layer on the first top electrode and the second top electrode and partially extending into the groove.

### BRIEF DESCRIPTION OF THE DRAWINGS

FIG. 1 is a top view illustrating an intermediate product of an organic light-emitting element.

FIG. 2A is a cross-sectional view illustrating an organic light-emitting element.

FIG. 2B is a cross-sectional view illustrating an organic light-emitting element.

FIG. 2C is a cross-sectional view illustrating an organic light-emitting element.

FIG. 2D is a cross-sectional view illustrating an organic light-emitting element.

FIG. 2E is a cross-sectional view illustrating an organic light-emitting element.

FIG. 3A is a cross-sectional view illustrating an organic light-emitting element.

FIG. 3B is a cross-sectional view illustrating an organic light-emitting element.

FIGS. 4A to 4D depict a method for manufacturing an organic light-emitting element according to some embodiments.

FIGS. 5A to 5C depict a method for manufacturing the organic light-emitting element according to some embodiments.

### DETAILED DESCRIPTION

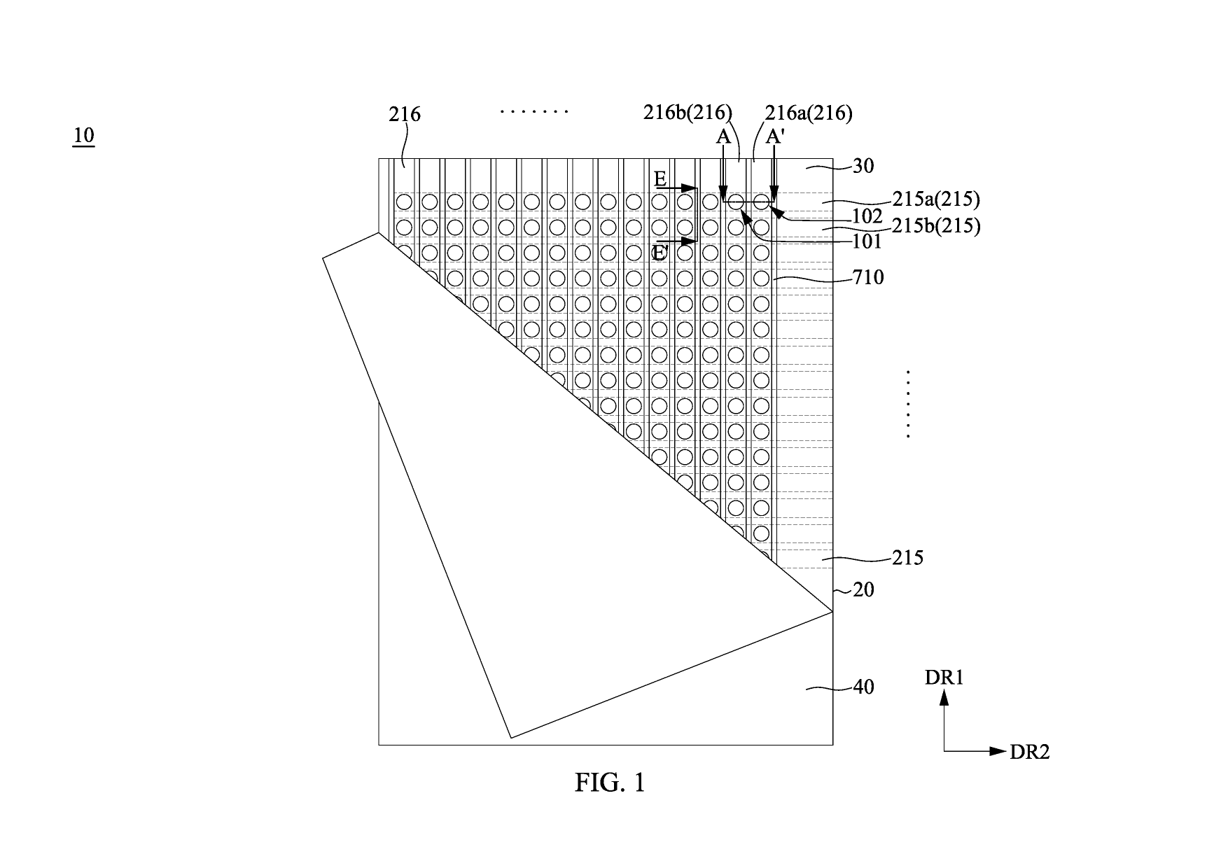

FIG. 1 is a top view illustrating an intermediate product of an organic light-emitting element 10. The organic light-emitting element 10 may include a light-emitting layer 20 and a cover layer 40 that locates over the light-emitting layer 20. For the light-emitting layer 20, a spacer structure 30 may be designed to provide an array of recesses for accommodating the light-emitting pixel array. In some embodiments, the spacer structure 30 serves as a pixel defined layer (PDL). In some embodiments, the spacer structure 30 may include a protrusion 310. In some embodiments, the protrusion 310 define pixel regions. In some embodiments, the spacer structure 30 may include photosensitive materials.

As shown in FIG. 1, the organic light-emitting element 10 may further include an electrode 215 (also referred to as a bottom electrode) and an electrode 216 (also referred to as a top electrode). In some embodiments, the electrode 215 is an anode, and the electrode 216 is a cathode. In some embodiments, the organic light-emitting element 10 may include multiple electrodes 215 and multiple electrodes 216, such as electrodes 215a, 215b, and electrodes 216a, 216b. In some embodiments, an extension direction DR2 of the electrode 215 is substantially perpendicular to an extension direction DR1 of the electrode 216. The organic light-emitting element 10 may further include a blocking strip structure 710. In some embodiments, the extension direction DR1 of the electrode 216 is substantially parallel to the extension direction DR1 of the blocking strip structure 710. In some embodiments, the extension direction DR2 of the electrode 215 is substantially perpendicular to the extension direction DR1 of the blocking strip structure 710.

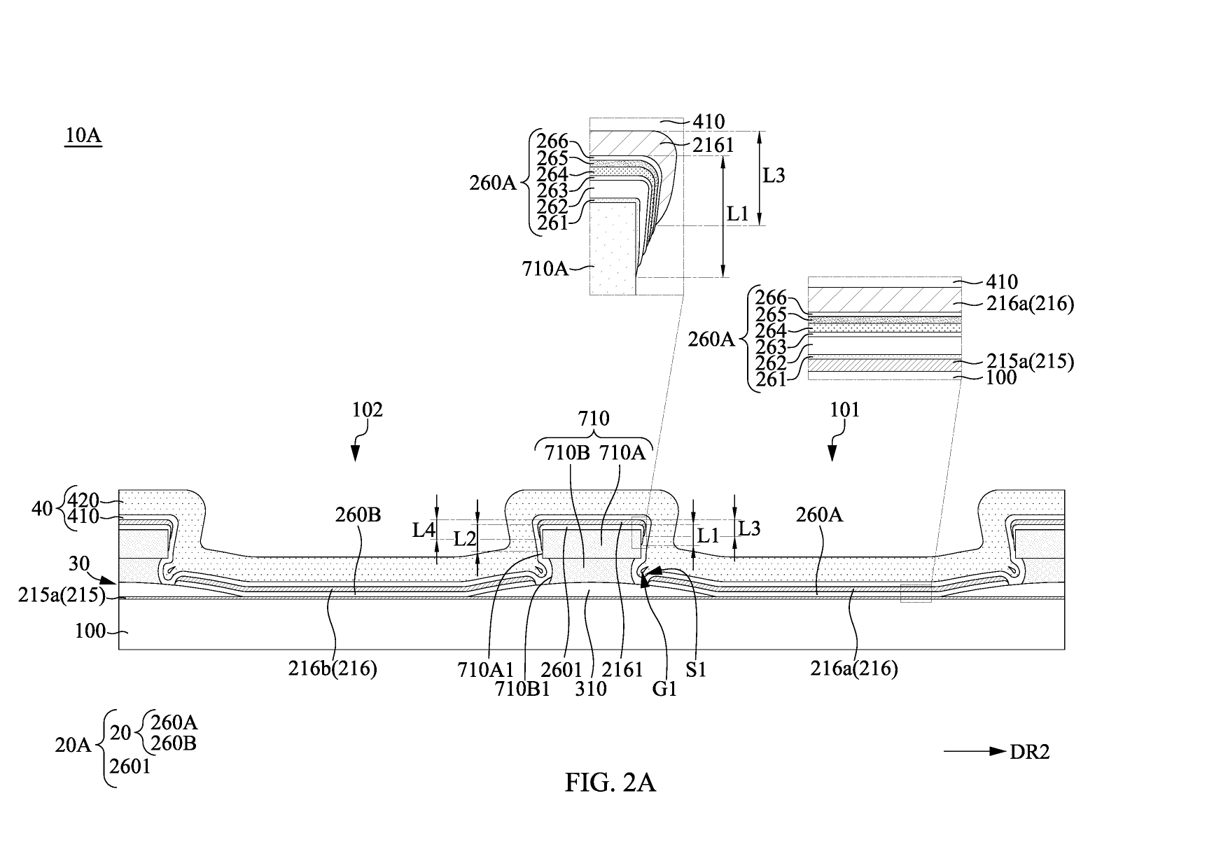

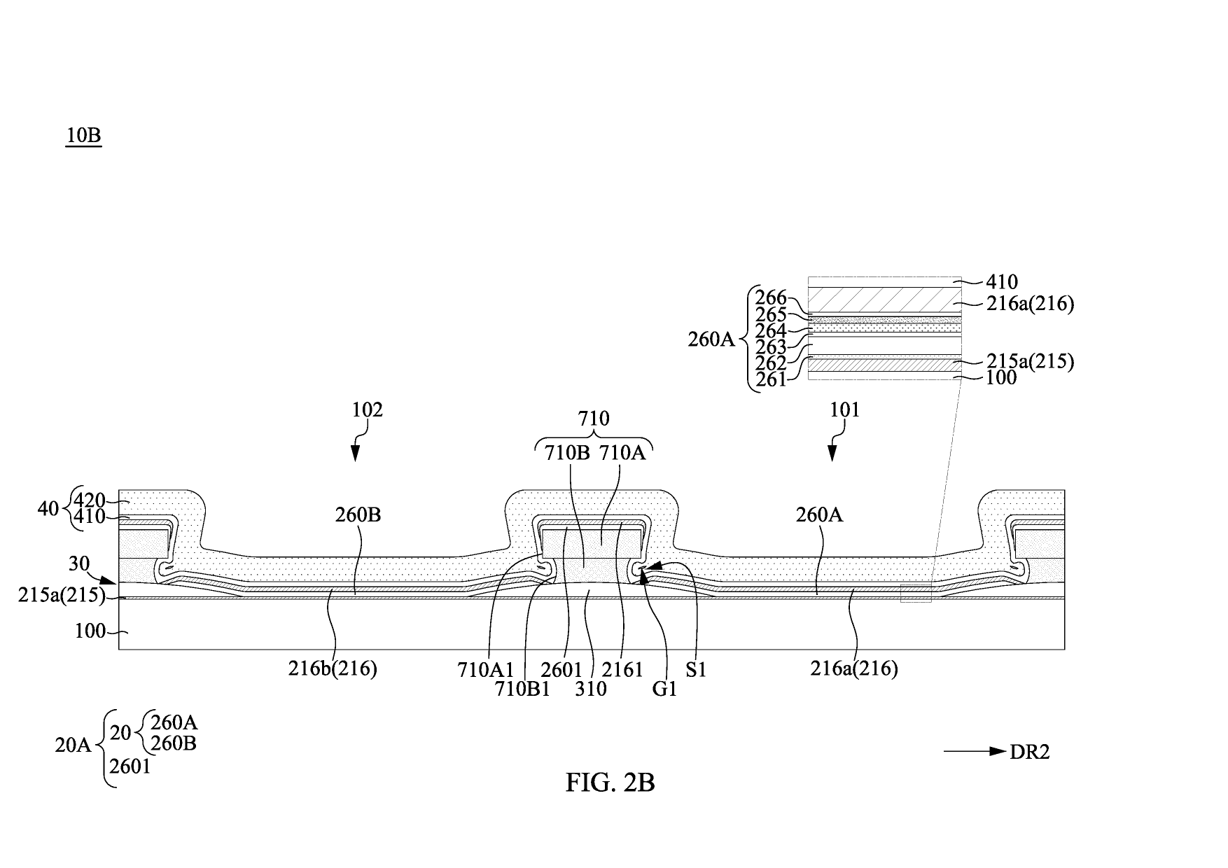

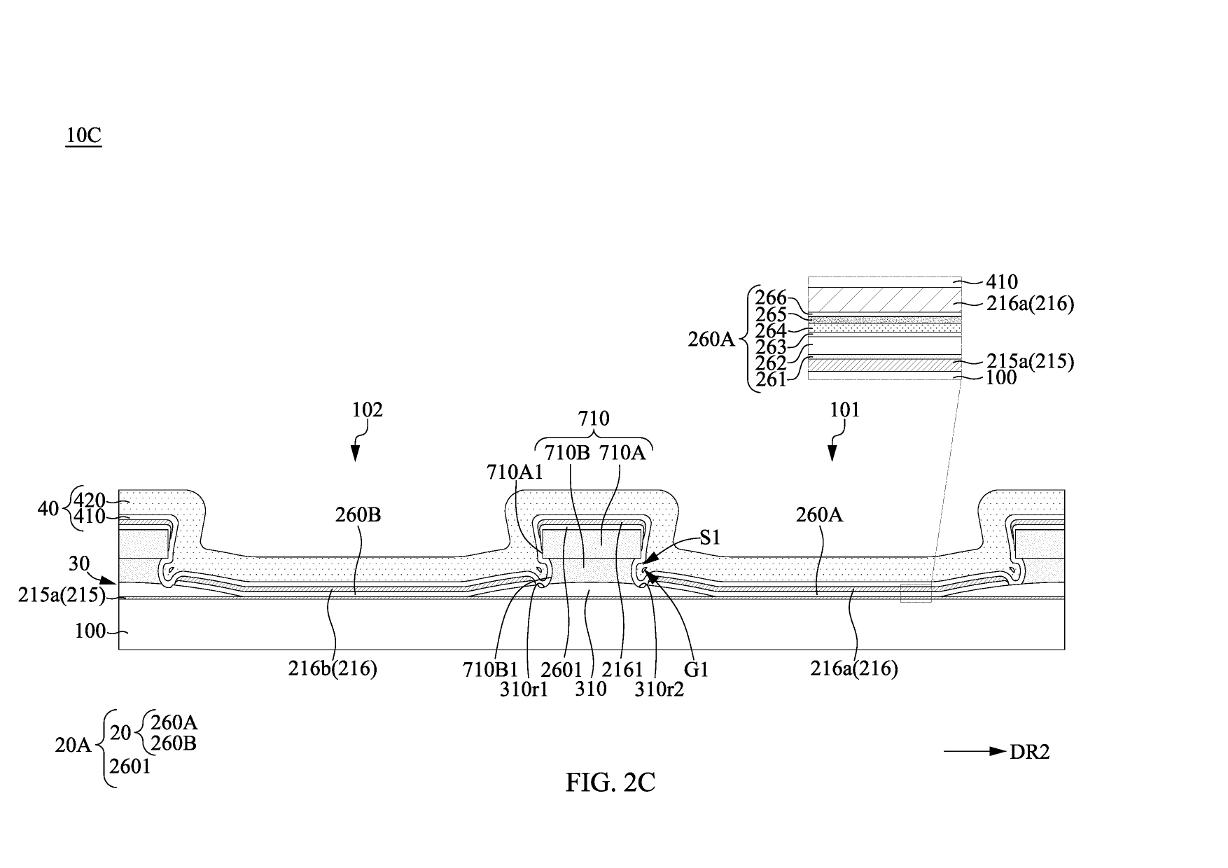

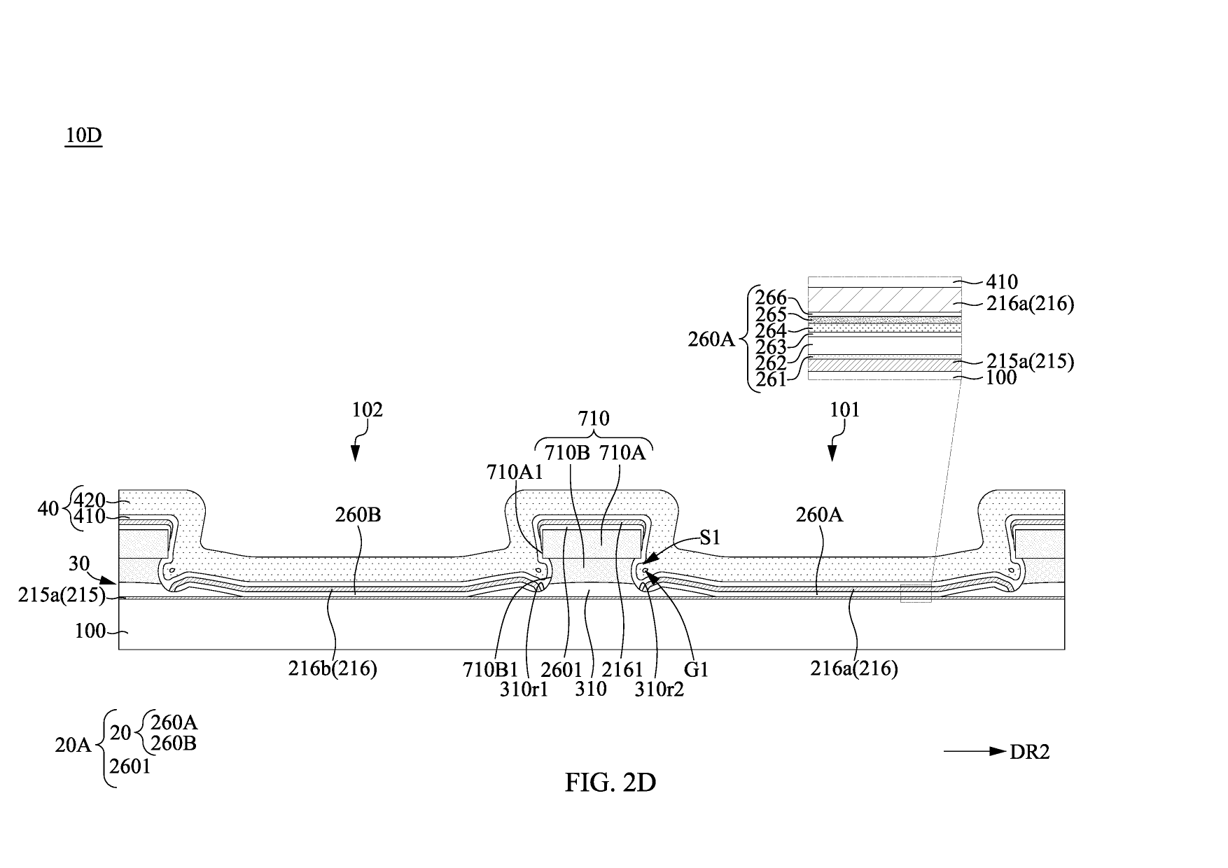

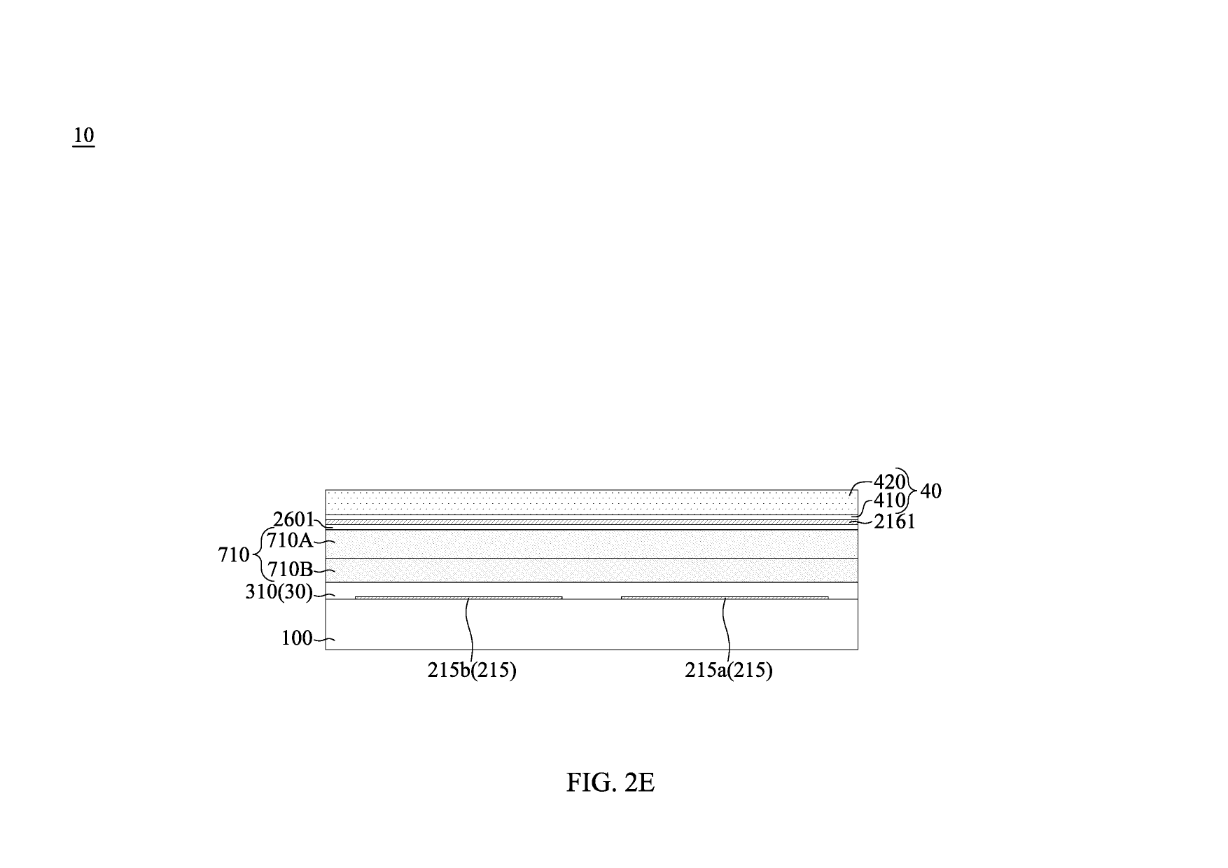

FIG. 2A is a cross-sectional view illustrating an organic light-emitting element 10A. In some embodiments, FIG. 2A is a cross-sectional view taken along a line A-A' in FIG. 1. The spacer structure 30 comprises several protrusions 310 to define a light-emitting pixel pattern. Recessed portions are located between two adjacent protrusions 310 and provide space for accommodating light-emitting pixels. One skilled in the art should understand that, when viewed from the cross-sectional view in FIG. 2A, the protrusions 310 are depicted in a discontinuous manner; however, when viewed from a top view in FIG. 1, they may be interconnected through other portions of the spacer structure 30.

As shown in FIG. 2A, in some embodiments, the organic light-emitting element 10 is, for example, a light-emitting element including an organic light-emitting diode (OLED) structure. In some embodiments, the organic light-emitting element 10 includes a plurality of organic light-emitting units (also referred to as light-emitting pixels), which, for example, comprise at least an organic light-emitting unit 101 (also referred to as a first organic light-emitting unit) and an organic light-emitting unit 102 (also referred to as a second organic light-emitting unit). In some embodiments, the organic light-emitting units 101 and 102 are located between the protrusions 310 and over a substrate 100. The organic light-emitting units 101 and 102 may emit light having the same wavelength or light having different wavelengths.

In some embodiments, the organic light-emitting element 10 includes the substrate 100, the electrode 215a (also referred to as the first bottom electrode), the electrode 216a (also referred to as the first top electrode), the electrode 216b (also referred to as the second top electrode), an electrode material layer 2161, an organic light-emitting layer structure 20A, the spacer structure 30 (also referred to as the pixel defining layer), and a cover layer 40.

In some embodiments, the substrate 100 may include a transistor array configured to correspond to light-emitting pixels within the light-emitting layer 20. The substrate 100 may include several capacitors. In some embodiments, more than one transistor is configured to form a circuit with a capacitor and a light-emitting pixel. In some embodiments, the substrate 100 may include glass.

In some embodiments, the organic light-emitting layer structure 20A is located on the electrode 215. In some embodiments, the organic light-emitting layer structure 20A includes the light-emitting layer 20 and an organic material layer 2601. In some embodiments, the light-emitting layer 20 includes an organic light-emitting layer 260A (also referred to as a first organic light-emitting layer) and an organic light-emitting layer 260B (also referred to as a second organic light-emitting layer).

In some embodiments, the electrode 215a is located on the substrate 100. In some embodiments, the electrode 215a is an anode. In some embodiments, the electrode 215a includes metallic materials, such as Ag, Al, Mg, Au, AlCu alloy, AgMo alloy, etc. In some embodiments, the electrode 215a includes indium tin oxide (ITO), indium zinc oxide (IZO), or other suitable materials. In some embodiments, the organic light-emitting layer 260A and the organic light-emitting layer 260B are located on the electrode 215a.

In some embodiments, the electrode 216a and the electrode 216b are located on the organic light-emitting layer structure 20A. In some embodiments, the electrode 216a is located on the organic light-emitting layer 260A, and the electrode 216b is located on the organic light-emitting layer 260B. In some embodiments, the electrode 216a is in contact with the organic light-emitting layer 260A, and the electrode 216b is in contact with the organic light-emitting layer 260B. In some embodiments, the electrodes 216a and 216b may further be located on the spacer structure 30 (or pixel defining layer). In some embodiments, the electrodes 216a and 216b include metallic materials, such as Ag, Al, Mg, Au, AlCu alloy, AgMo alloy, etc. In some embodiments, the electrodes 216a and 216b include ITO, IZO, or other suitable materials.

In some embodiments, the blocking strip structure 710 is located on the substrate 10. In some embodiments, the electrode 216a and the electrode 216b are separated by the blocking strip structure 710. In some embodiments, the electrode 216a and the electrode 216b are electrically isolated or insulated from each other by the blocking strip structure 710. In some embodiments, a thickness of the blocking strip structure 710 is equal to or greater than 1 μm, for example, from 1 μm to 4 μm or from 2 μm to 3 μm. In some embodiments, the thickness of the blocking strip structure 710 is greater than a thickness of the electrode 216. In some embodiments, the thickness of the blocking strip structure 710 is more than 10 times the thickness of the electrode 216, for example, 20 to 30 times. In some embodiments, the blocking strip structure 710 may include photosensitive materials. In some embodiments, the blocking strip structure 710 may include inorganic oxides, such as silicon oxide, silicon nitride, or silicon oxynitride.

In some embodiments, the blocking strip structure 710 includes a blocking strip 710A and a blocking strip 710B. In some embodiments, the blocking strip 710B (also referred to as a first blocking strip) is located between the electrode 216a and the electrode 216b, the blocking strip 710A (also referred to as a second blocking strip) is located on the blocking strip 710B, and a width of the blocking strip 710A is greater than a width of the blocking strip 710B. In some embodiments, a sidewall 710B1 of the blocking strip 710B is recessed relative to a sidewall 710A1 of the blocking strip 710A. In some embodiments, the sidewall 710B1 of the blocking strip 710B comprises a concave curved surface. In some embodiments, the blocking strip 710A and the blocking strip 710B include different materials. In some embodiments, the blocking strip 710A and the blocking strip 710B may include different photosensitive materials. For example, the blocking strip 710A and the blocking strip 710B may include different photoresist materials. In some embodiments, the blocking strip 710A and the blocking strip 710B may include different inorganic oxides, for example, the blocking strip 710A may include silicon oxide, while the blocking strip 710B may include silicon nitride or silicon oxynitride.

In some embodiments, the electrode material layer 2161 is located on an upper surface and sidewalls of the blocking strip structure 710, and the electrode material layer 2161 is separated from the electrode 216a and the electrode 216b. In some embodiments, the electrode material layer 2161 is located on an upper surface and the sidewall 710A1 of the blocking strip 710A. In some embodiments, the electrode material layer 2161 includes an extension portion located on the sidewalls of the blocking strip structure 710 and tapering towards the substrate 100. In some embodiments, an extension portion of the electrode material layer 2161 is located on the sidewalls 710A1 of the blocking strip 710A and tapers towards the substrate 100. In some embodiments, the electrode material layer 2161 includes two extension portions located on two opposite sidewalls 710A1 of the blocking strip 710A, and extension lengths of these two extension portions may be the same or different. For example, an extension length L3 of one extension portion of the electrode material layer 2161 is greater than an extension length L4 of the other extension portion.

In some embodiments, the organic light-emitting layer 260A is located between the electrode 215a and the electrode 216a, and the organic light-emitting layer 260B is located between the electrode 215a and the electrode 216b. In some embodiments, the organic light-emitting layer 260A and the organic light-emitting layer 260B are separated by the blocking strip structure 710. In some embodiments, the thickness of the blocking strip structure 710 is greater than thicknesses of the organic light-emitting layers 260A and 260B. In some embodiments, the thickness of the blocking strip structure 710 is more than ten times the thicknesses of the organic light-emitting layers 260A and 260B, for example, ten to twenty times. In some embodiments, the organic light-emitting layers 260A and 260B emit light having the same or different colors. In some embodiments, a light-emission wavelength of the organic light-emitting layer 260A is the same as a light-emission wavelength of the organic light-emitting layer 260B. In some embodiments, a light-emission wavelength of the organic light-emitting layer 260B is greater than a light-emission wavelength of the organic light-emitting layer 260A.

In some embodiments, the organic light-emitting layers 260A and 260B and the organic material layer 2601 include organic materials. These organic materials may be disposed within any material layer of the organic light-emitting layers 260A and 260B and the organic material layer 2601, according to different embodiments. In some embodiments, the organic materials have an absorption rate of greater than or equal to 50% for a specific wavelength. In some embodiments, the organic materials have an absorption rate of greater than or equal to 60% for a specific wavelength. In some embodiments, the organic materials have an absorption rate of greater than or equal to 70% for a specific wavelength. In some embodiments, the organic materials have an absorption rate of greater than or equal to 80% for a specific wavelength. In some embodiments, the organic materials have an absorption rate of greater than or equal to 90% for a specific wavelength. In some embodiments, the organic materials have an absorption rate of greater than or equal to 95% for a specific wavelength. In some embodiments, the specific wavelength is not greater than 400 nm. In some embodiments, the specific wavelength is not greater than 350 nm. In some embodiments, the specific wavelength is not greater than 300 nm. In some embodiments, the specific wavelength is not greater than 250 nm. In some embodiments, the specific wavelength is not greater than 200 nm. In some embodiments, the specific wavelength is not greater than 150 nm. In some embodiments, the specific wavelength is not greater than 100 nm.

As shown in FIG. 2A, in some embodiments, the organic light-emitting layers 260A and 260B and the organic material layer 2601 each includes multiple material layers, such as a hole injection layer (HIL) 261, a hole transport layer (HTL) 262, an electron blocking layer (EBL) 263, an organic emission layer (EM) 264, an electron transport layer (ETL) 265, and an electron injection layer (EIL) 266. In some embodiments, the organic light-emitting unit 101 includes the electrode 215a (also referred to as the first bottom electrode), the organic light-emitting layer 260A, and the electrode 216a (also referred to as the first top electrode). In some embodiments, the organic light-emitting unit 102 includes the electrode 215a (also referred to as the first bottom electrode), the organic light-emitting layer 260B, and the electrode 216b (also referred to as the second top electrode).

In some embodiments, the organic material layer 2601 is located on the blocking strip structure 710. In some embodiments, the organic material layer 2601 includes organic materials. In some embodiments, the electrode material layer 2161 is located on the blocking strip structure 710. In some embodiments, the organic material layer 2601 is separated from the organic light-emitting layers 260A and 260B. In some embodiments, materials of the organic material layer 2601 are the same as materials of the organic light-emitting layers 260A and 260B.

In some embodiments, the organic material layer 2601 includes an extension portion that is located on a sidewall of the blocking strip structure 710 and tapers towards the substrate 100. In some embodiments, an extension portion of the organic material layer 2601 is located on the sidewall 710A1 of the blocking strip 710A and tapers towards the substrate 100. In some embodiments, the organic material layer 2601 includes two extension portions located on the two opposing sidewalls 710A1 of the blocking strip 710A, and extension lengths of these two extension portions may be same or different. For example, an extension length L1 of one extension portion of the organic material layer 2601 may be greater than an extension length L2 of the other extension portion.

In some embodiments, the organic material layer 2601 includes the hole injection layer (HIL) 261, the hole transport layer (HTL) 262, the electron blocking layer (EBL) 263, the organic emission layer (EM) 264, the electron transport layer (ETL) 265, and the electron injection layer (EIL) 266. In some embodiments, the hole injection layer (HIL) 261, the hole transport layer (HTL) 262, the electron blocking layer (EBL) 263, the organic emission layer (EM) 264, the electron transport layer (ETL) 265, and the electron injection layer (EIL) 266 of the organic material layer 2601 each includes two extension portions located on the two opposing sidewalls 710A1 of the blocking strip 710A. In some embodiments, extension portions of the hole injection layer (HIL) 261, the hole transport layer (HTL) 262, the electron blocking layer (EBL) 263, the organic emission layer (EM) 264, the electron transport layer (ETL) 265, and the electron injection layer (EIL) 266 of the organic material layer 2601 may have the same or different extension lengths.

In some embodiments, the spacer structure 30 is located on the substrate 100 and partially covers the electrode 215a. In some embodiments, the spacer structure 30 is located between the organic light-emitting layers 260A and 260B. In some embodiments, the spacer structure 30 is located between the electrode 216a and the electrode 216b. In some embodiments, a pattern of the spacer structure 30 is designed according to a pixel arrangement. In some embodiments, the spacer structure 30 serves as a pixel defined layer (PDL). In some embodiments, the spacer structure 30 may includes protrusions 310. In some embodiments, the protrusions 310 define pixel regions. In some embodiments, the electrode 215a is partially covered by the protrusions 310.

In some embodiments, the blocking strip structure 710 is located on the spacer structure 30 (or pixel defined layer). In some embodiments, the thickness of the blocking strip structure 710 is 0.2 to 2 times or 0.3 to 1.2 times a thickness of the spacer structure 30 (or the pixel defined layer). In some embodiments, widths of blocking strips 710A and 710B are both less than a width of the protrusions 310. In some embodiments, the thickness of the spacer structure 30 is equal to or greater than 0.5 μm, for example, from 0.5 μm to 2 μm or from 0.6 μm to 1 μm.

In some embodiments, a local surface of the spacer structure 30 (or the pixel defining layer), the sidewall 710B1 of the blocking strip 710B, and an end portion of the electrode 216a define a space S1. In some embodiments, the electrode 216a and the blocking strip 710B are spaced apart from each other by the space S1. In some embodiments, the local surface of the spacer structure 30 (or the pixel defining layer), the sidewall 710B1 of the blocking strip 710B, and an end portion of the electrode 216b define the space S1. In some embodiments, the electrode 216b and the blocking strip 710B are spaced apart from each other by the space S1. In some embodiments, the electrode 216a and the electrode 216b are spaced apart from each other by the blocking strip 710B and the space S1.

In some embodiments, the spacer structure 30 (or the pixel defining layer) includes organic insulating materials. In some embodiments, the spacer structure 30 includes photosensitive materials. In some embodiments, the spacer structure 30 may further include quantum dots, which have excellent light absorption efficiency. In some embodiments, the spacer structure 30 may further include carbon black materials, such as carbon black nanoparticles, carbon black-containing conductive fibers, or the like. In some embodiments, the spacer structure 30 may further include black body materials, which have an absorption rate of 90%, 95%, 99%, 99.5%, or more than 99.9% for visible light.

In some embodiments, the absorption rate of the spacer structure 30 for a specific wavelength is greater than or equal to 50%. In some embodiments, the absorption rate of the spacer structure 30 for a specific wavelength is greater than or equal to 60%. In some embodiments, the absorption rate of the spacer structure 30 for a specific wavelength is greater than or equal to 70%. In some embodiments, the absorption rate of the spacer structure 30 for a specific wavelength is greater than or equal to 80%. In some embodiments, the absorption rate of the spacer structure 30 for a specific wavelength is greater than or equal to 90%. In some embodiments, the absorption rate of the spacer structure 30 for a specific wavelength is greater than or equal to 95%. In some embodiments, the specific wavelength is not greater than 400 nm. In some embodiments, the specific wavelength is not greater than 350 nm. In some embodiments, the specific wavelength is not greater than 300 nm. In some embodiments, the specific wavelength is not greater than 250 nm. In some embodiments, the specific wavelength is not greater than 200 nm. In some embodiments, the specific wavelength is not greater than 150 nm. In some embodiments, the specific wavelength is not greater than 100 nm.

In some embodiments, the cover layer 40 includes a capping layer 410 and an encapsulation layer 420. In some embodiments, the capping layer 410 is disposed on the electrodes 216a, 216b, and the blocking strip structure 710, and is substantially conformal with non-planar upper surfaces of the electrodes 216a, 216b, and the blocking strip structure 710. In some embodiments, the capping layer 410 is located in or fills in the space S1. The capping layer 410 may include dielectric materials or inorganic insulating materials, such as silicon oxide. In some embodiments, the capping layer 410 may include hole transport layer materials, which are used to extract light lost within the organic light-emitting element to enhance light-emitting efficiency. The capping layer 410 may also be referred to as a light extraction layer.

In some embodiments, the encapsulation layer 420 is disposed on the capping layer 410 and is substantially conformal with a non-planar upper surface of the capping layer 410. The encapsulation layer 420 may include oxides, such as silicon oxide. In some embodiments, the encapsulation layer 420 is substantially conformal with the non-planar upper surface of the capping layer 410 and comprises multiple recesses corresponding to the organic light-emitting layers 260A and 260B. In some embodiments, the encapsulation layer 420 is located in or fills in the space S1. In some embodiments, the encapsulation layer 420 further comprises a void G1. In some embodiments, the void G1 is located in the space S1. In some embodiments, the electrode 216a and the electrode 216b are separated from each other by the blocking strip 710B and the capping layer 410, the encapsulation layer 420, and the void G1 in the space S1. The encapsulation layer 420 may include polymer organic materials, such as epoxy-based materials.

According to some embodiments of the present disclosure, multiple electrodes 216 are separated from each other by the blocking strip structure 710 and intersect perpendicularly with multiple electrodes 215 in multiple light-emitting units (or light-emitting pixels). A height difference provided by the blocking strip structure 710 allows the multiple electrodes 216 to be physically separated without the need to pattern the electrode materials using photolithography and etching processes to form multiple separated electrodes 216. As such, the process steps of the electrodes 216 can be simplified, and individual control of multiple light-emitting units (or light-emitting pixels) to light up at a single point can be achieved , enabling the organic light-emitting element 10 to display various predetermined light-emitting patterns. For example, when the organic light-emitting element 10 is applied in sighting devices, it can be designed according to ballistics to present multi-point display images.

Furthermore, according to some embodiments of the present disclosure, the height difference provided by the blocking strip structure 710 allows the multiple electrodes 216 to be physically separated, thereby reducing or avoiding damages to the organic light-emitting layers 260A and 260B beneath the electrodes 216 caused by etching processes, thereby improving the reliability and yield of the organic light-emitting element 10.

In addition, according to some embodiments of the present disclosure, the sidewall 710B1 of the blocking strip 710B is recessed relative to the sidewall 710A1 of the blocking strip 710A, making it difficult for a comprehensive electrode material layer to form on the recessed sidewall 710B1. Consequently, the blocking strip structure 710 can more effectively separate multiple electrodes 216 from each other.

Furthermore, in some embodiments of the present disclosure, the electrode 216a and the electrode 216b are separated by the blocking strip 710B and the capping layer 410, the encapsulation layer 420, and the void G1 in the space S1. A multilayer structure and multiple heterogeneous interfaces by the capping layer 410, the encapsulation layer 420, and the void G1 separate the electrode 216a from the electrode 216b, thereby more effectively electrically isolating or insulating the electrode 216a from the electrode 216b, effectively preventing potential short circuits.

Additionally, according to some embodiments of the present disclosure, the organic light-emitting layer 260A and the organic light-emitting layer 260B are separated by the blocking strip structure 710. As a result, there is no need to use photolithography etching processes to pattern organic light-emitting materials to form multiple separated organic light-emitting layers. Therefore, the process steps for the organic light-emitting layer can be simplified.

FIG. 2B is a cross-sectional view illustrating an organic light-emitting element 10B. In some embodiments, FIG. 2B is a cross-sectional view illustrating the organic light-emitting element 10 in FIG. 1. In some embodiments, FIG. 2B illustrates a cross-sectional view along the line A-A' in FIG. 1. In some embodiments, FIG. 2B illustrates a cross-sectional view along line A-A' in FIG. 1 and only depicts the light-emitting region. A structure of FIG. 2B is similar to the structure of FIG. 2A, with differences described as follows.

In some embodiments, the electrode 216a and the electrode 216b extend beneath the blocking strip structure 710. In some embodiments, the electrode 216a and the electrode 216b extend beneath the blocking strip 710A. In some embodiments, the electrode 216a and the electrode 216b extend to and contact the recessed sidewall 710B1 of the blocking strip 710B.

According to some embodiments of the present disclosure, the electrode 216a and the electrode 216b extend to and contact the recessed sidewall 710B1 of the blocking strip 710B. Through the design of inner curved surface of the sidewall 710B1, a volume of the space S1 beneath the blocking strip 710A is increased, thereby allowing more portions of the electrode 216a and the electrode 216b to be formed therein by evaporation. As such, through the design of the inner curved surface of the sidewall 710B1 of the blocking strip 710B, the electrode material layer can be further effectively disconnected, thereby more thoroughly physically separating multiple electrodes 216. Consequently, this can effectively prevent short circuits between adjacent light-emitting units (or light-emitting pixels), thereby avoiding the issue of single-point lighting failure.

FIG. 2C is a cross-sectional view illustrating an organic light-emitting element 10C. In some embodiments, FIG. 2C is a cross-sectional view of the organic light-emitting element 10 in FIG. 1. In some embodiments, FIG. 2C illustrates a cross-sectional view along the line A-A' in FIG. 1. In some embodiments, FIG. 2C illustrates a cross-sectional view along the line A-A' in FIG. 1 and only depicts a light-emitting region. A structure of FIG. 2C is similar to the structure of FIG. 2A, with differences described as follows.

In some embodiments, the protrusions 310 of the spacer structure 30 (or pixel defining layer) comprise grooves 310r1 and 310r2. In some embodiments, the grooves 310r1 and 310r2 are located on both sides of the blocking strip 710B and each connected to the space S1 thereover.

According to some embodiments in the present disclosure, through designs of the grooves 310r1 and 310r2 and their connection to the space S1, an overall spatial volume beneath the blocking strip 710A is increased, thereby further enhancing the step difference created by the blocking strip structure 710. Consequently, by further increasing the step difference, the electrode material layers can be more effectively disconnected, allowing the multiple electrodes 216 to be physically separated more thoroughly.

FIG. 2D is a cross-sectional view illustrating an organic light-emitting element 10D. In some embodiments, FIG. 2D is a cross-sectional view of the organic light-emitting element 10 of FIG. 1. In some embodiments, FIG. 2D illustrates a cross-sectional view along the line A-A' in FIG. 1. In some embodiments, FIG. 2D illustrates a cross-sectional view along the line A-A' in FIG. 1 and only depicts a light-emitting region. A structure of FIG. 2D is similar to the structure of FIG. 2A, with differences as described below.

In some embodiments, the electrode 216a and the electrode 216b extend into the grooves 310r1 and 310r2 beneath the blocking strip 710A.

According to some embodiments in the present disclosure, the electrode 216a and the electrode 216b further extend into the grooves 310r1 and 310r2. Through designs of the grooves 310r1 and 310r2 and their connection to the space S1, an overall spatial volume beneath the blocking strip 710A can be increased, thereby allowing more portions of the electrodes 216a and 216b to be formed therein by evaporation. As such, by increasing the overall spatial volume beneath the blocking strip 710A, the electrode material layers can be more effectively disconnected, allowing the multiple electrodes 216 to be physically separated more thoroughly. Consequently, short circuits between adjacent light-emitting units (or light-emitting pixels) can be effectively avoided, thereby avoiding the issue of single-point lighting failure.

FIG. 2E is a cross-sectional view illustrating the organic light-emitting element 10. In some embodiments, FIG. 2E illustrates a cross-sectional view along a line E-E' in FIG. 1. In some embodiments, FIG. 2E illustrates a cross-sectional view along the line E-E' in FIG. 1 and only depicts a light-emitting region.

In some embodiments, the electrode 215a and the electrode 215b are separated from each other by the spacer structure 30 (or pixel defining layer). In some embodiments, the electrode 215a and the electrode 215b are separated from each other by the spacer structure 30 (or pixel defining layer) and the blocking strip structure 710. In some embodiments, the electrode 215a and the electrode 215b are separated from each other by the blocking strips 710A and 710B.

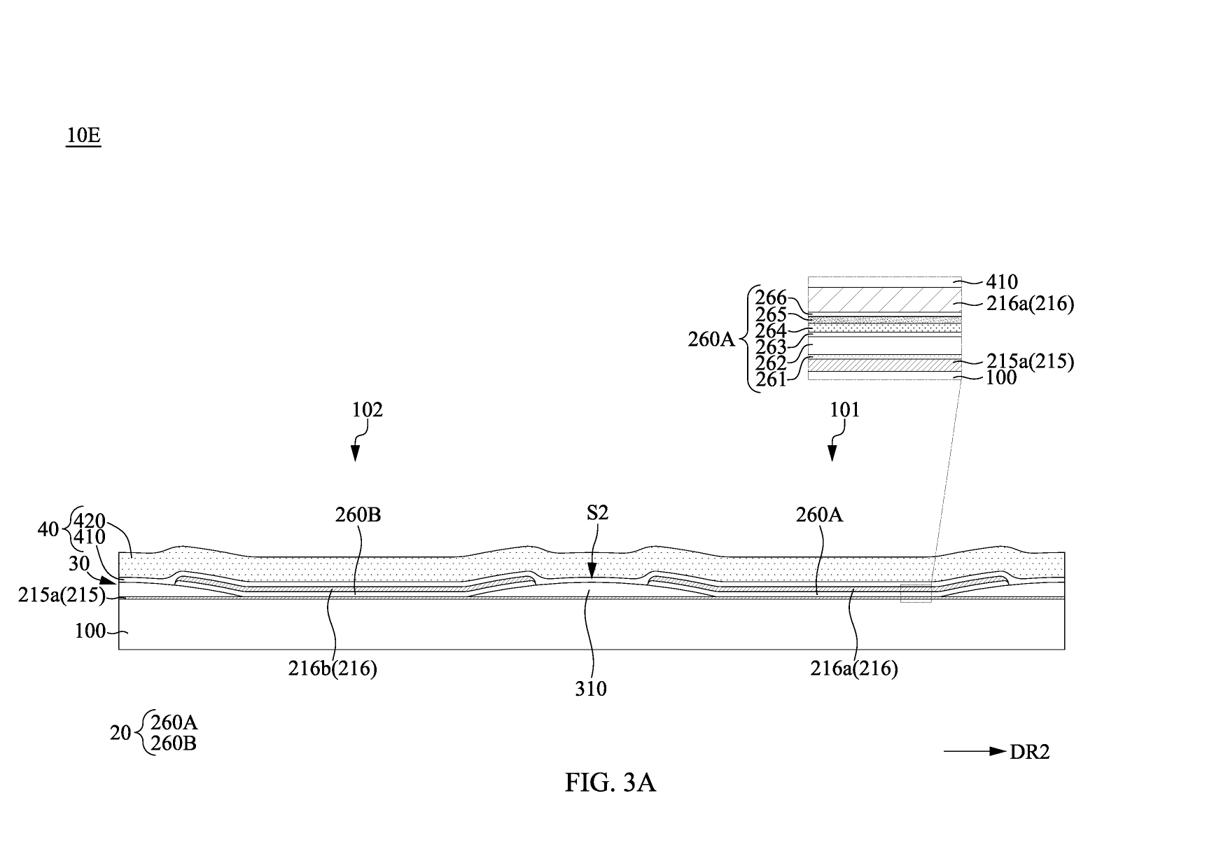

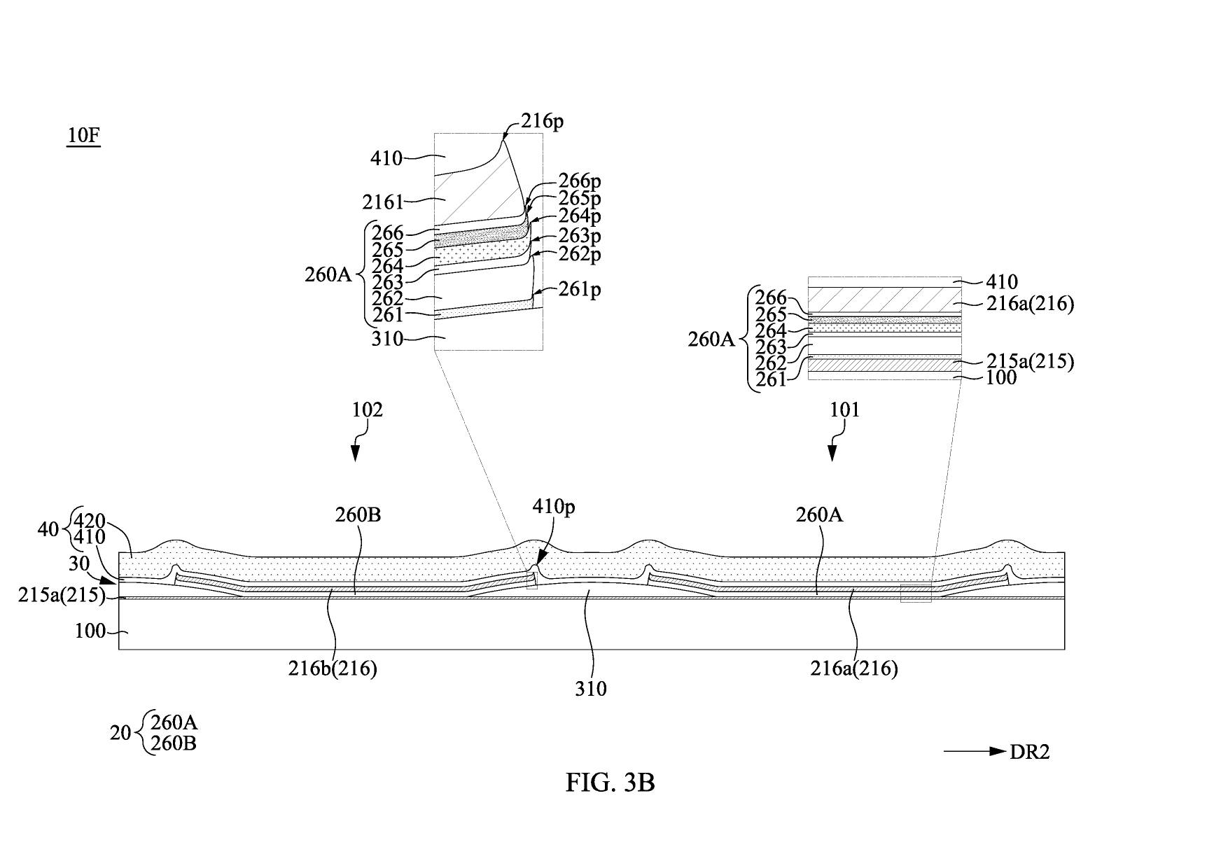

FIG. 3A is a cross-sectional view illustrating an organic light-emitting element 10E. In some embodiments, FIG. 3A is a cross-sectional view illustrating the organic light-emitting element 10 in FIG. 1. In some embodiments, FIG. 3A illustrates a cross-sectional view along the line A-A' in FIG. 1. In some embodiments, FIG. 3A illustrates a cross-sectional view along the line A-A' in FIG. 1 and only depicts the light-emitting region. The structure of FIG. 3A is similar to the structure of FIG. 2A, with differences as described as follows.

In some embodiments, the electrode 216a, the electrode 216b, and a local upper surface of the spacer structure 30 (or pixel defining layer) define a groove S2. In some embodiments, the electrode 216a and the electrode 216b are separated by the groove S2. In some embodiments, the electrode 216a partially extends onto the protrusions 310 (or pixel defining layer), and a thickness of the electrode 216a tapers towards the electrode 216b. In some embodiments, the electrode 216b partially extends onto the protrusions 310 (or pixel defining layer), and a thickness of the electrode 216b tapers towards the electrode 216a.

In some embodiments, the capping layer 410 covers the electrode 216a and the electrode 216b and partially extends into the groove S2. In some embodiments, the encapsulation layer 420 covers the electrode 216a and the electrode 216b and partially extends into the groove S2.

According to some embodiments in the present disclosure, multiple electrodes 216 are separated from each other by the groove S2. As such, there is no blocking strip structure 710 over the protrusions 310 (or the pixel defining layer), and the capping layer 410 and the encapsulation layer 420 can be formed on a relatively flat surface. As a result, the capping layer 410 has fewer stress concentration points, making the capping layer 410 less prone to damages, and an overall size of the organic light-emitting element 10E can be further reduced.

FIG. 3B is a cross-sectional view illustrating an organic light-emitting element 10F. In some embodiments, FIG. 3B is a cross-sectional view illustrating the organic light-emitting element 10 in FIG. 1. In some embodiments, FIG. 3B illustrates a cross-sectional view along the line A-A' in FIG. 1. In some embodiments, FIG. 3B illustrates a cross-sectional view along the line A-A' in FIG. 1 and only depicts the light-emitting region. A structure of FIG. 3B is similar to the structure of FIG. 2A, with differences as described as follows.

In some embodiments, an end portion of the electrode 216 extends onto the protrusions 310 (or pixel defining layer) and includes an upwardly extending protrusion portion 216p. In some embodiments, an end portion of the organic light-emitting layer 260A extends onto the protrusions 310 (or pixel defining layer) and includes multiple upwardly extending protrusion portions. In some embodiments, multiple protrusion portions of the organic light-emitting layer 260A partially overlap in the vertical direction. In some embodiments, the capping layer 410 includes a protrusion portion 410p located over the protrusion portion 216p.

In some embodiments, an end portion of the hole injection layer (HIL) 261 extends onto the protrusions 310 (or the pixel defining layer) and includes an upwardly extending protrusion portion 261p. In some embodiments, an end portion of the hole transport layer (HTL) 262 extends onto the protrusions 310 (or the pixel defining layer) and includes an upwardly extending protrusion portion 262p. In some embodiments, an end portion of the electron blocking layer (EBL) 263 extends onto the protrusions 310 (or the pixel defining layer) and includes an upwardly extending protrusion portion 263p. In some embodiments, an end portion of the organic emission layer (EM) 264 extends onto the protrusions 310 (or the pixel defining layer) and includes an upwardly extending protrusion portion 264p. In some embodiments, an end portion of the electron transport layer (ETL) 265 extends onto the protrusions 310 (or the pixel defining layer) and includes an upwardly extending protrusion portion 265p. In some embodiments, an end portion of the electron injection layer (EIL) 266 extends onto the protrusions 310 (or the pixel defining layer) and includes an upwardly extending protrusion portion 266p. In some embodiments, heights of the protrusion portions of the respective layers are less than thicknesses of the respective layers.

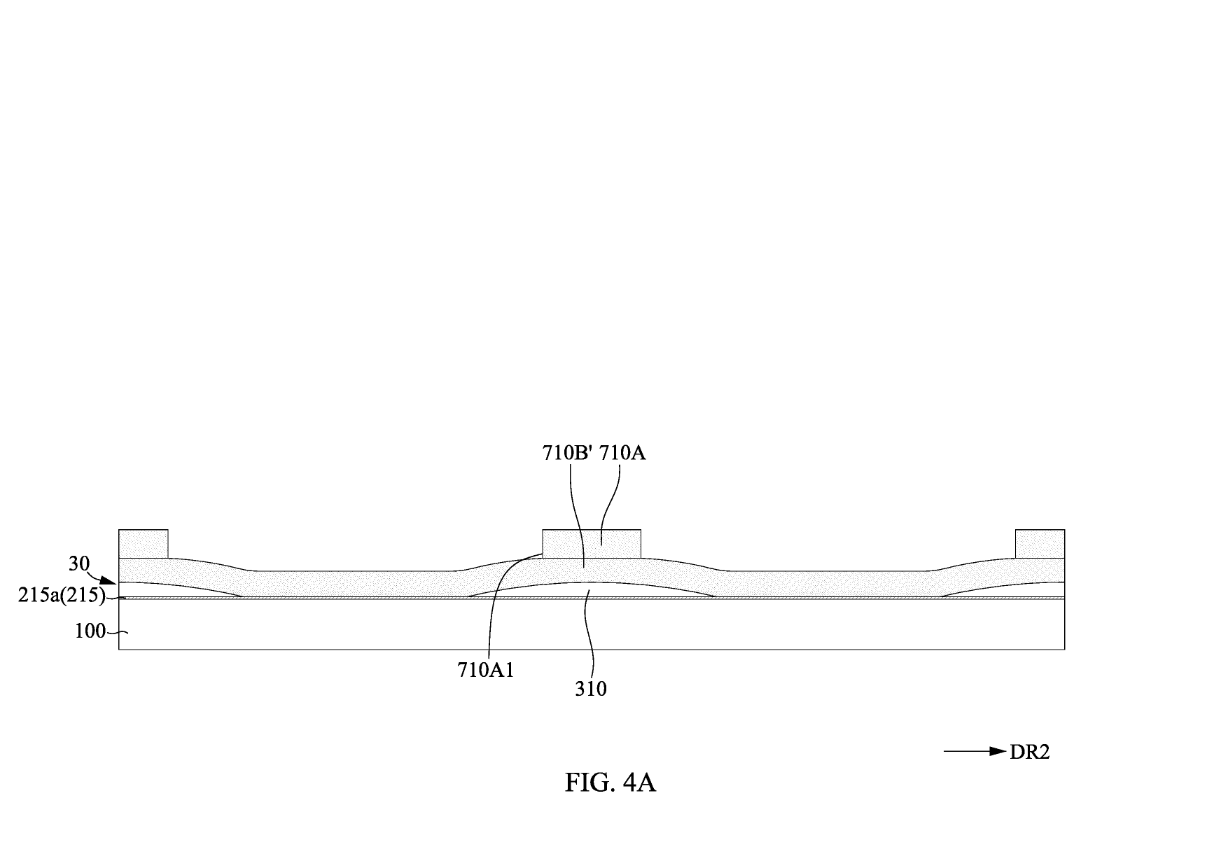

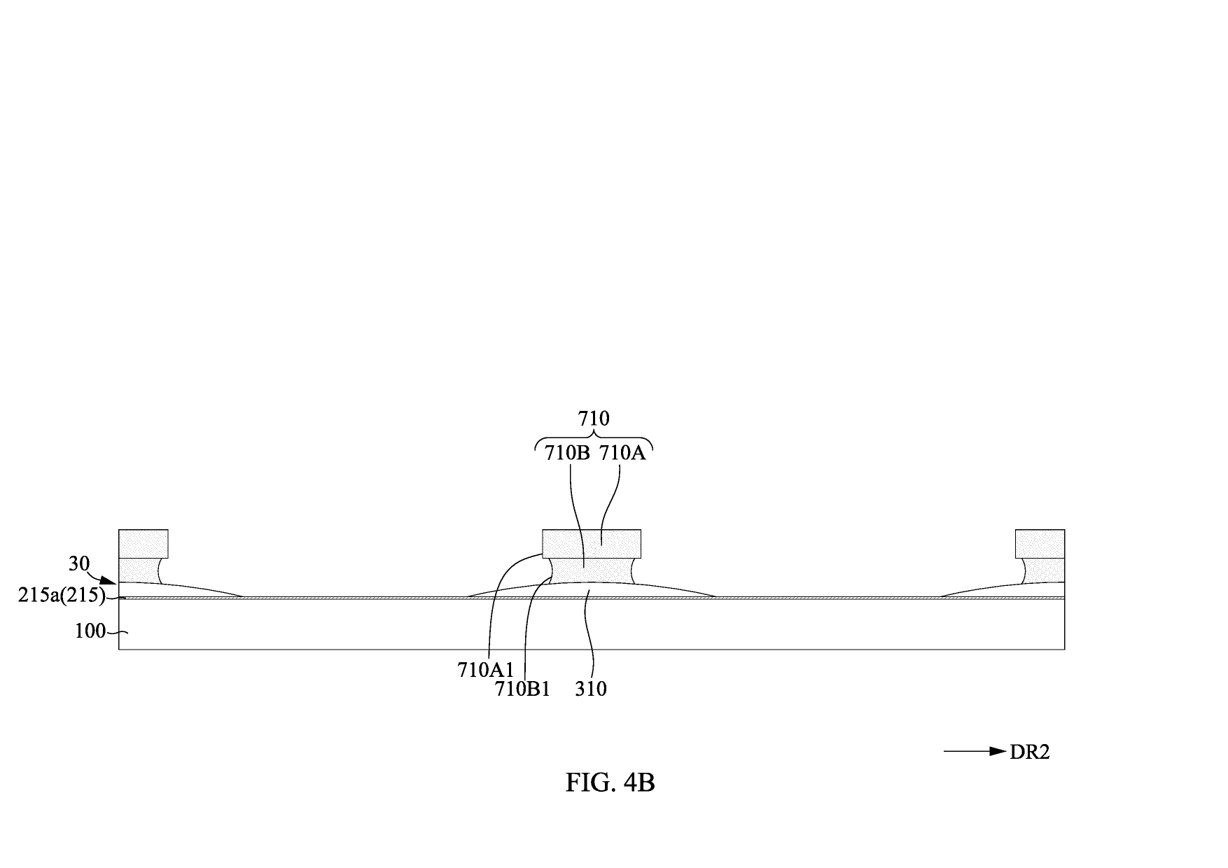

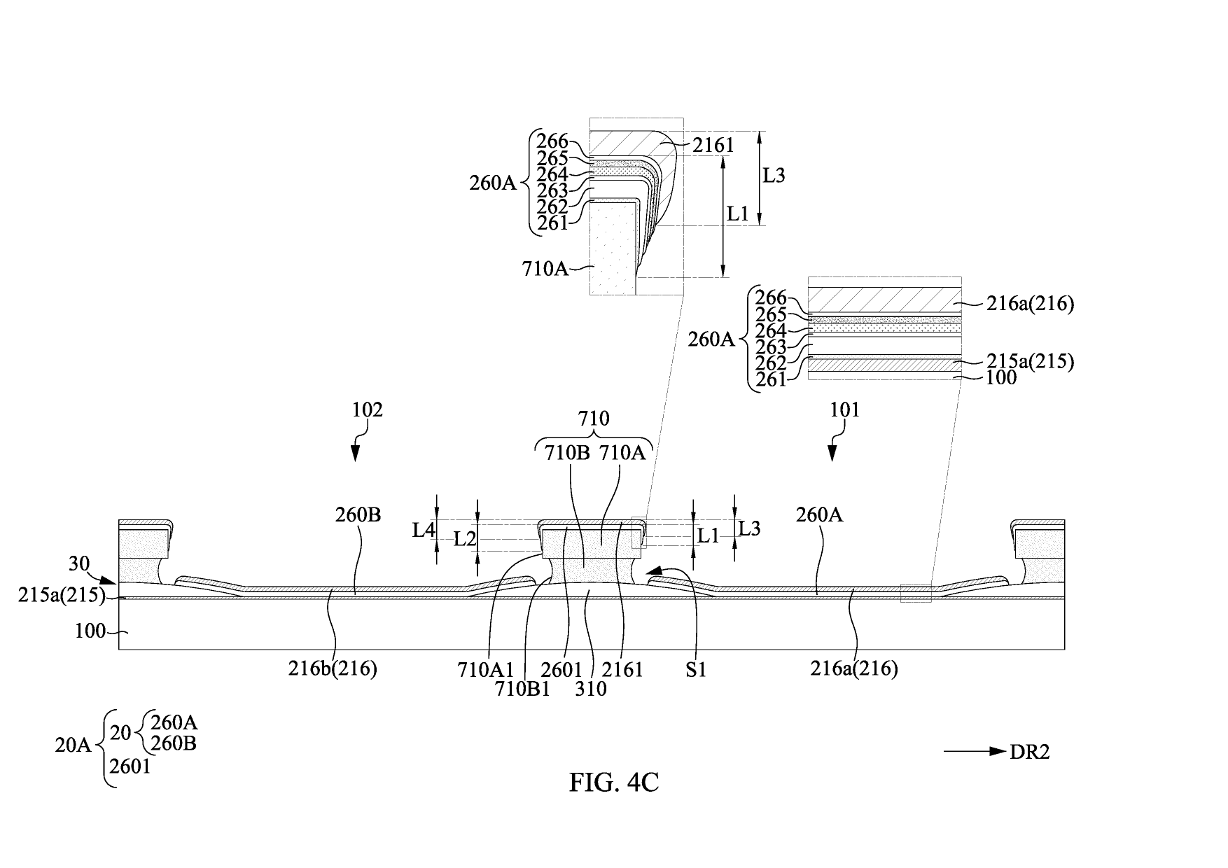

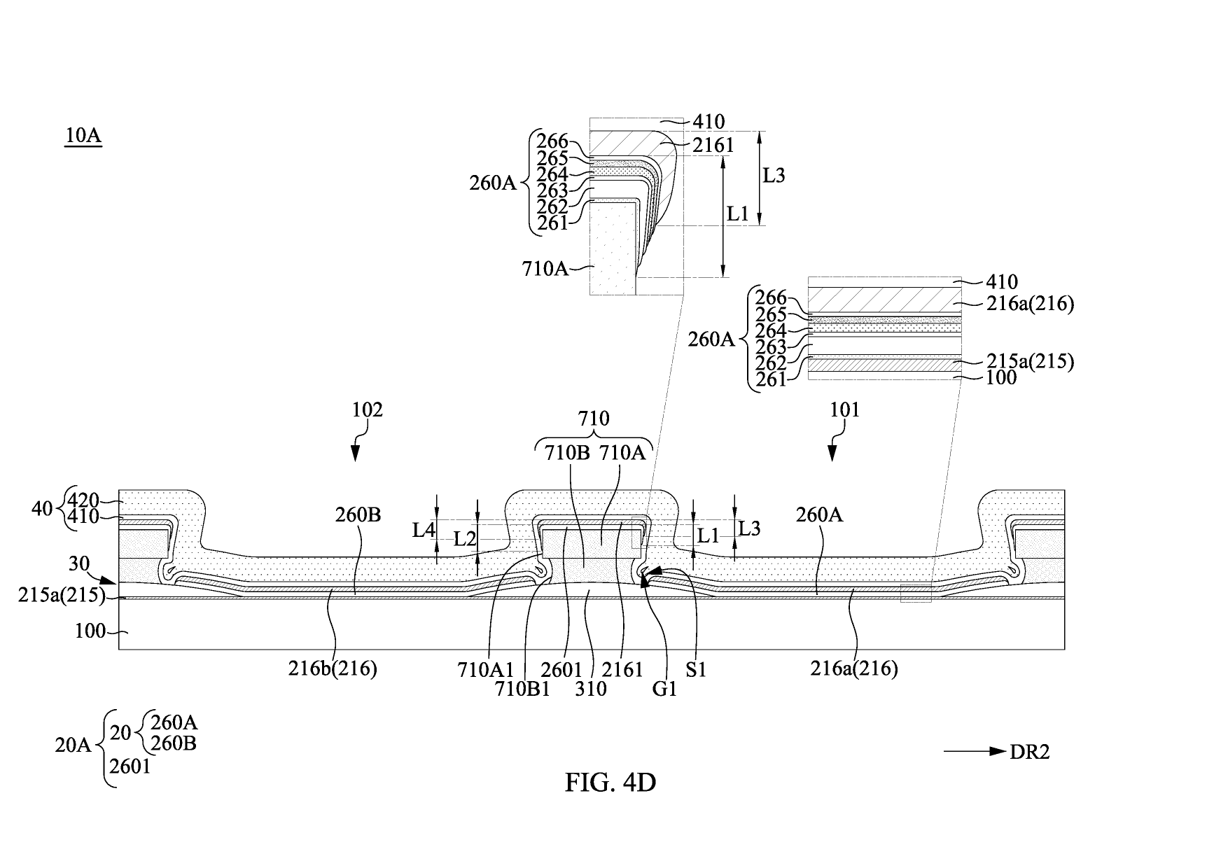

FIGS. 4A to 4D depict a method for manufacturing the organic light-emitting element 10A according to some embodiments.

As shown in FIG. 4A, in some embodiments, a substrate 100 is provided, an electrode 215a is disposed on the substrate 100, and a plurality of protrusions 310 (or spacer structures 30) are formed on the electrode 215a. In some embodiments, multiple electrodes 215 are disposed on the substrate 100 (refer to FIG. 1), and the spacer structures 30 are formed on the multiple electrodes 215. The multiple electrodes 215 may be fabricated by photolithographic etching processes. Subsequently, in some embodiments, a blocking material layer 710B' is formed on the electrode 215 and the protrusions 310 (or pixel defining layer), and blocking strips 710A are formed on the blocking material layer 710B' by photolithographic etching processes. In some embodiments, the blocking strips 710A and the blocking material layer 710B' may include different photosensitive materials, such as the blocking strips 710A and the blocking material layer 710B' may include different photoresist materials.

As shown in FIG. 4B, in some embodiments, the blocking material layer 710B' is etched according to a pattern of the blocking strips 710A to form blocking strips 710B, with a sidewall 710B1 of the blocking strips 710B recessed relative to a sidewall 710A1 of the blocking strips 710A. In some embodiments, the blocking material layer 710B' is etched by a wet etching step, resulting in the sidewall 710B1 of the blocking strips 710B having an undercut structure. In some embodiments, the blocking material layer 710B' is etched by a wet etching step, resulting in the sidewall 710B1 of the blocking strips 710B having a concave curved surface. Thus, a blocking strip structure 710 is formed.

As shown in FIG. 4C, in some embodiments, an organic light-emitting layer structure 20A and an electrode material layer 2161 are formed on the spacer structure 30, the electrode 215a, and the blocking strip structure 710.

In some embodiments, an electrode material layer is formed over the blocking strip structure 710 and the substrate 100, such that the electrode material layer is cut off by the blocking structure 70, thereby forming separated electrodes 216a and 216b. In some embodiments, a complete electrode material layer is formed on the spacer structure 30, the electrode 215a, and the blocking strip structure 710 by evaporation, such that the complete electrode material layer is cut off by the blocking strip structure 710, thereby forming separated electrodes 216a and 216b, and leaving an electrode material layer 2161 on the blocking strip structure 710.

In some embodiments, an organic light-emitting material layer is formed over the blocking strip structure 710 and the substrate 100, such that the organic light-emitting material layer is cut off by the blocking structure 70 to form an organic light-emitting layer 260A and an organic light-emitting layer 260B which are separated from each other. In some embodiments, a complete organic light-emitting material layer is formed on the spacer structure 30, the electrode 215a, and the blocking strip structure 710 by evaporation, so that the complete organic light-emitting material layer is cut off by the blocking strip structure 710 to form separate organic light-emitting layers 260A and 260B and an organic material layer 2601 remaining on the blocking strip structure 710. Thus, organic light-emitting units 101 and 102 are formed.

In some embodiments, a hole injection layer (HIL) 261 is disposed on surfaces of the spacer structure 30, the electrode 215a, and the blocking strip structure 710, a hole transport layer (HTL) 262 is disposed on the hole injection layer (HIL) 261, an electron blocking layer (EBL) 263 is disposed on the hole transport layer (HTL) 262, an organic emission layer (EM) 264 is disposed on the electron blocking layer (EBL) 263, subsequently, an electron transport layer (ETL) 265 is disposed on the organic emission layer (EM) 264, and an electron injection layer (EIL) 266 is located on the electron transport layer (ETL) 265. In some embodiments, the hole injection layer (HIL) 261, the hole transport layer (HTL) 262, the electron blocking layer (EBL) 263, the organic emission layer (EM) 264, the electron transport layer (ETL) 265, and the electron injection layer (EIL) 266 are formed by evaporation.

As shown in FIG. 4D, in some embodiments, a capping layer 410 is disposed on the electrodes 216a and 216b. In some embodiments, the capping layer 410 is formed by evaporation. Subsequently, in some embodiments, an encapsulation layer 420 is disposed on the capping layer 410. In some embodiments, the encapsulation layer 420 is formed by evaporation. Thus, an organic light-emitting element 10A as shown in FIG. 2A is formed.

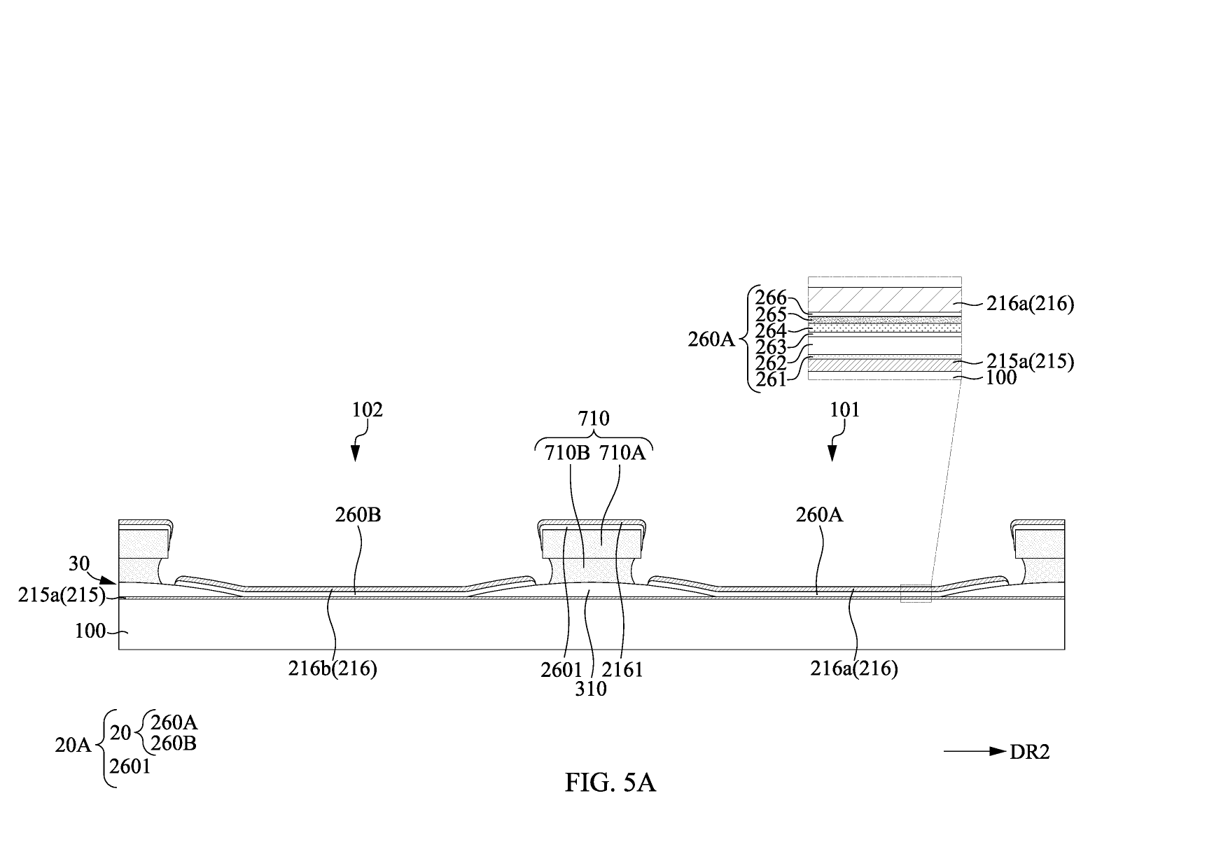

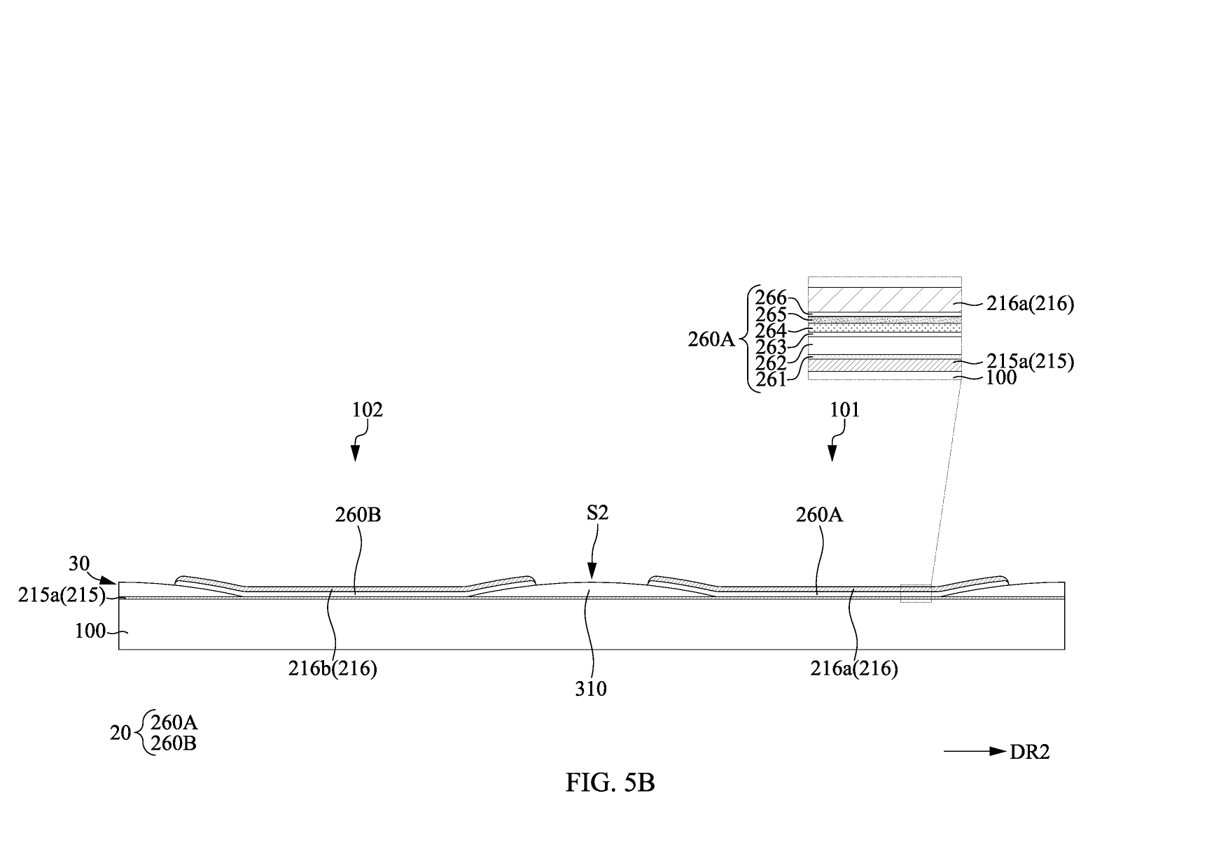

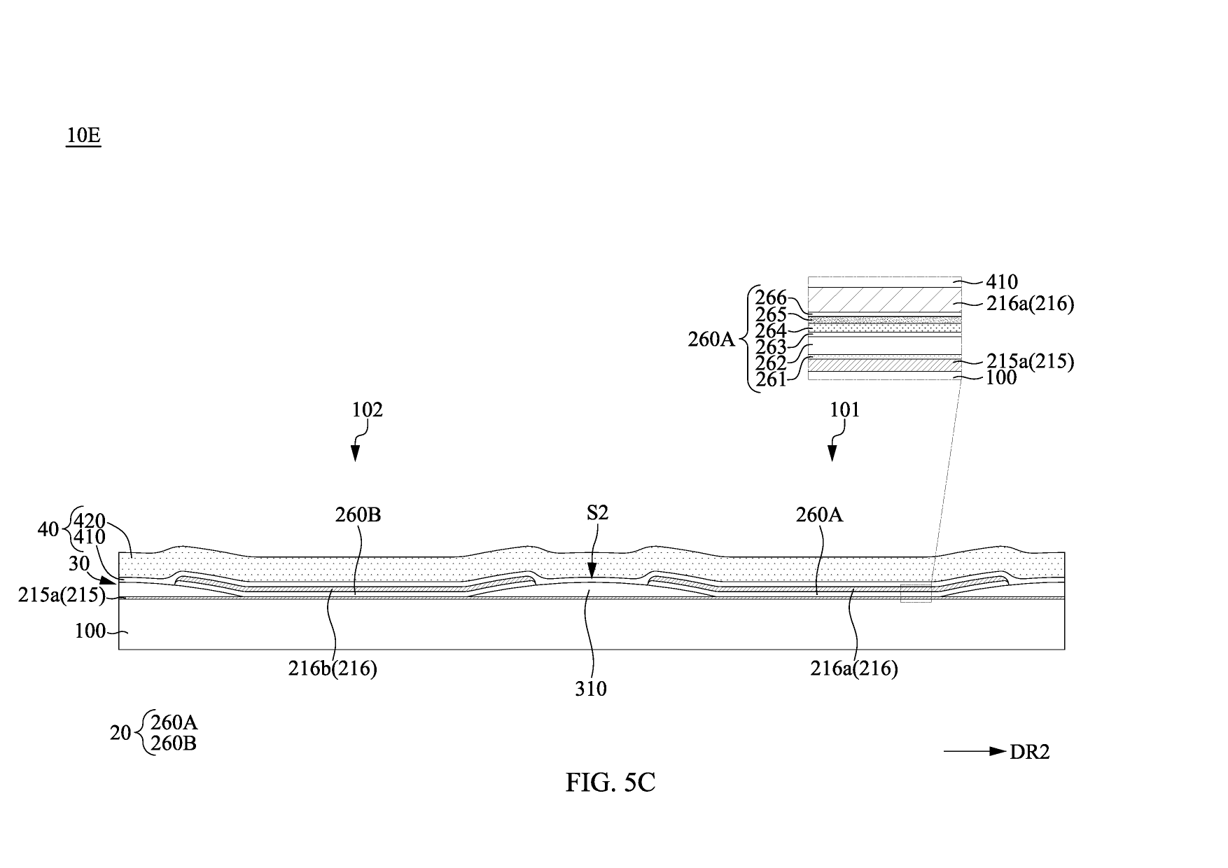

FIGS. 5A to 5C depict a method for manufacturing an organic light-emitting element 10E according to some embodiments.

As shown in FIG. 5A, in some embodiments, steps shown in FIGS. 4A to 4C are performed to form a structure shown in FIG. 4C.

As shown in FIG. 5B, in some embodiments, the blocking strip structure 710 is removed to form a groove S2 defined by the electrode 216a, the electrode 216b, and a local upper surface of the protrusions 310 (or the pixel definition layer). In some embodiments, the blocking strip structure 710 is removed by a lift-off process.

As shown in FIG. 5C, in some embodiments, a capping layer 410 is disposed on the electrodes 216a and 216b. In some embodiments, the capping layer 410 is formed by evaporation. In some embodiments, the capping layer 410 is formed over the electrodes 216a and 216b and partially extends into the groove S2. Subsequently, in some embodiments, an encapsulation layer 420 is disposed on the capping layer 410. In some embodiments, the encapsulation layer 420 is formed by evaporation. Thus, an organic light-emitting element 10E as shown in FIG. 3A is formed.

According to some embodiments in the present disclosure, after removing the blocking strip structure 710, surface height differences of an overall structure can be significantly reduced, and the surface uniformity of the overall structure can be improved, so that the capping layer 410 and the encapsulation layer 420 can be formed on a relatively flat surface. Consequently, the capping layer 410 has fewer stress concentration points, making it less susceptible to damages, and an overall size of the organic light-emitting element 10E can be further reduced.

In some embodiments, with reference to FIGS. 5A, 5B, and 3B simultaneously, the electrodes 216a and 216b are formed to contact the blocking strip structure 710. Upon removal of the blocking strip structure 710, the electrodes 216a and 216b are subjected to tension, resulting in the formation of the protrusion portion 216p. In some embodiments, with reference to FIGS. 5A, 5B, and 3B simultaneously, the organic light-emitting layers 260A and 260B are formed to contact the blocking strip structure 710. Upon removal of the blocking strip structure 710, the organic light-emitting layer 260A and the organic light-emitting layer260B are subjected to tension, resulting in the formation of multiple protrusion portions. Subsequently, the capping layer 410 and the encapsulation layer 420 can be disposed to form an organic light-emitting element 10F as shown in FIG. 3B.

The aforementioned content generally outlines the features of some implementations, allowing one skilled in the art to better understand various aspects of the present disclosure. One skilled in the art should understand that the present disclosure can be easily used as a foundation to design or modify other processes and structures to achieve the same objectives and/or achieve the same advantages as the embodiments described in the present application. One skilled in the art should also understand that such equivalent structures do not depart from the spirit and the scope of the content disclosed in the present disclosure, and various changes, substitutions, and modifications can be made without departing from the spirit and the scope of the disclosure.

What is claimed is:

1. An organic light-emitting element, comprising:
a substrate;
a first bottom electrode located on the substrate;
an organic light-emitting layer structure located on the first bottom electrode; and
a first top electrode and a second top electrode located on the organic light-emitting layer structure, wherein extension directions of the first top electrode and the second top electrode are substantially perpendicular to an extension direction of the first bottom electrode, and the first top electrode and the second top electrode are separated from each other.

2. The organic light-emitting element according to claim 1, further comprising:
a pixel defining layer located on the substrate, wherein the first top electrode, the second top electrode, and a local upper surface of the pixel defining layer define a groove, and the first top electrode and the second top electrode are separated by the groove.

3. The organic light-emitting element according to claim 2, wherein the first top electrode partially extends onto the pixel defining layer, and a thickness of the first top electrode tapers towards the second top electrode.

4. The organic light-emitting element according to claim 2, wherein an end portion of the first top electrode extends onto the pixel defining layer and comprises an upwardly extending protrusion portion.

5. The organic light-emitting element according to claim 2, further comprising:
a capping layer covering the first top electrode and the second top electrode and partially extending into the groove.

6. The organic light-emitting element according to claim 1, further comprising:
a blocking strip structure located on the substrate, and the first top electrode and the second top electrode being separated by the blocking strip structure.

7. The organic light-emitting element according to claim 6, wherein the blocking strip structure comprises:
a first blocking strip located between the first top electrode and the second top electrode; and
a second blocking strip located on the first blocking strip, a width of the second blocking strip being greater than a width of the first blocking strip.

8. The organic light-emitting element according to claim 7, wherein a sidewall of the first blocking strip is recessed relative to a sidewall of the second blocking strip.

9. The organic light-emitting element according to claim 7, wherein a sidewall of the first blocking strip comprises a concave curved surface.

10. The organic light-emitting element according to claim 6, further comprising:
an electrode material layer located on an upper surface and sidewalls of the blocking strip structure, and separated from the first top electrode and the second top electrode.

11. The organic light-emitting element according to claim 10, wherein the electrode material layer comprises an extension portion located on the sidewalls of the blocking strip structure and tapering towards the substrate.

12. The organic light-emitting element according to claim 6, wherein the extension directions of the first top electrode and the second top electrode are substantially parallel to an extension direction of the blocking strip structure.

13. The organic light-emitting element according to claim 6, wherein the organic light-emitting layer structure comprises:
a first organic light-emitting layer located between the first bottom electrode and the first top electrode; and
a second organic light-emitting layer located between the first bottom electrode and the second top electrode, wherein the first organic light-emitting layer and the second organic light-emitting layer are separated by the blocking strip structure.

14. The organic light-emitting element according to claim 6, wherein the organic light-emitting layer structure comprises:
a first organic light-emitting layer and a second organic light-emitting layer, with the first top electrode and the second top electrode being respectively located on the first organic light-emitting layer and the second organic light-emitting layer; and
an organic material layer located on the blocking strip structure and separated from the first organic light-emitting layer and the second organic light-emitting layer.

15. The organic light-emitting element according to claim 6, further comprising:
a pixel defining layer located on the substrate and located between the first top electrode and the second top electrode, wherein the blocking strip structure is located on the pixel defining layer.

16. A method for manufacturing an organic light-emitting element, comprising:
providing a substrate;
disposing a first bottom electrode on the substrate;
forming a blocking strip structure on the substrate, wherein the blocking strip structure comprises a first blocking strip and a second blocking strip located on the first blocking strip;
forming an organic light-emitting layer structure on the first bottom electrode and the blocking strip structure; and
forming a top electrode material layer on the blocking strip structure and the substrate, such that the top electrode material layer is cut off by the second blocking strip to form a first top electrode and a second top electrode that are separated from each other.

17. The manufacturing method according to claim 16, further comprising:
forming a pixel defining layer on the substrate and partially covering the first bottom electrode; and
forming the blocking strip structure on the pixel defining layer, wherein the top electrode material layer is cut off by a height difference between the second blocking strip and the pixel defining layer.

18. The manufacturing method according to claim 17, wherein forming the blocking strip structure comprises:
forming a blocking material layer on the pixel defining layer;
forming the second blocking strip on the blocking material layer; and
etching the blocking material layer according to a pattern of the second blocking strip to form the first blocking strip, such that a sidewall of the first blocking strip is recessed relative to a sidewall of the second blocking strip.

19. The manufacturing method according to claim 17, further comprising:
removing the blocking strip structure to form a groove defined by the first top electrode, the second top electrode, and a local upper surface of the pixel defining layer.

20. The method for manufacturing according to claim 19, further comprising:
forming a capping layer on the first top electrode and the second top electrode and partially extending into the groove.
